(19) United States
(12) Patent Application Publication
(10) Pub. No.: US 2024/0313722 A1
(43) Pub. Date: Sep. 19, 2024

(54) OPERATIONAL AMPLIFIER CIRCUIT

(71) Applicant: ROHM CO., LTD., Kyoto (JP)

(72) Inventor: Hiroki NORIMATSU, Kyoto (JP)

(21) Appl. No.: 18/599,307

(22) Filed: Mar. 8, 2024

(30) Foreign Application Priority Data
Mar. 14, 2023 (JP) 2023-039917

(51) Int. Cl. H03F 3/45

(52) U.S. Cl. CPC H03F 3/45269; H03F 2200/129

(57) ABSTRACT

An operational amplifier circuit includes: a differential input stage; a gain stage; an output stage configured to be connected to a load; a replica of the output stage without being connected to the load; and a feedback circuit that receives a main output signal output from the output stage and a dummy output signal output from the replica, and supplies a feedback signal according to an error between the main output signal and the dummy output signal to the gain stage.

### CROSS-REFERENCE TO RELATED APPLICATION

The present invention claims priority under 35 U.S.C. § 119 to Japanese Patent Application No. 2023-039917, filed on Mar. 14, 2023, the entire contents of which are incorporated herein by reference.

### TECHNICAL FIELD

The present disclosure relates to an operational amplifier circuit.

### BACKGROUND

An operational (OP) amplifier (differential amplifier) is used to amplify a difference between two input voltages. A gain margin and a phase margin are indicators of stability of the operational amplifier.

In a configuration of a typical operational amplifier, as an output load capacitance increases, a phase margin decreases and an oscillation stability decreases. When a specific load capacitance exceeds 1,000 pF, the phase margin often falls below 30 degrees.

### BRIEF DESCRIPTION OF DRAWINGS

The accompanying drawings, which are incorporated in and constitute a part of the specification, illustrate embodiments of the present disclosure.

FIG. 1 is a block diagram of an operational amplifier circuit according to an embodiment.

FIG. 2 is a view showing a phase margin of an operational amplifier circuit.

FIG. 3 is a view showing gain characteristics of the operational amplifier circuit.

FIG. 4 is a circuit diagram of an operational amplifier circuit according to an embodiment.

FIG. 5 is a circuit diagram showing an example of the operational amplifier circuit of FIG. 4.

FIG. 6 is a circuit diagram showing an example of the operational amplifier circuit of FIG. 4.

FIG. 7 is a circuit diagram showing an example of the operational amplifier circuit of FIG. 4.

FIG. 8 is a circuit diagram showing an example of the operational amplifier circuit of FIG. 4.

FIG. 9 is a circuit diagram of an operational amplifier circuit according to Modification 1.

FIG. 10 is a circuit diagram of an operational amplifier circuit according to Modification 2.

FIG. 11 is a circuit diagram of an operational amplifier circuit according to Modification 3.

FIG. 12 is a circuit diagram of an operational amplifier circuit according to Modification 4.

FIG. 13 is a circuit diagram of an operational amplifier circuit according to Modification 5.

FIG. 14 is a circuit diagram of an operational amplifier circuit according to Modification 6.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### OVERVIEW OF EMBODIMENTS

An overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments (examples or modifications) disclosed herein.

An operational amplifier circuit according to an embodiment includes: a differential input stage; a gain stage; an output stage configured to be connected to a load; a replica of the output stage without being connected to the load; and a feedback circuit that receives a main output signal output from the output stage and a dummy output signal output from the replica and supplies a feedback signal according to an error between the main output signal and the dummy output signal to the gain stage.

Large load capacitance creates a pole that causes a phase delay. This causes an increase in amount of attenuation of a main output at the output stage, thereby increasing a mismatch between the main output and a dummy output. With the above configuration, when the load capacitance is large, by applying feedback to the gain stage to reduce the mismatch, a new zero point can be added, the phase delay of the pole can be canceled, and circuit stability can be improved. With this method, since it is not necessary to always maintain a bias current to be large, an increase in power consumption is suppressed. Further, when the load capacitance is small and the mismatch between the main output and the dummy output is small, the feedback circuit does not affect the gain stage.

In one embodiment, the gain stage may be a folded cascode circuit, and the feedback signal may be supplied as a bias voltage of the gain stage.

In one embodiment, the output stage may be class AB including a first high-side transistor and a first low-side transistor, and the replica may include a second high-side transistor having a gate connected to a gate of the first high-side transistor, and a second low-side transistor having a gate connected to a gate of the first low-side transistor.

In one embodiment, the output stage and the replica may have corresponding transistors of a same size. As a result, it is possible to detect the mismatch with high accuracy.

In one embodiment, a transistor size of the replica and a transistor size of the output stage may be different from each other. In this case, the output stage and the replica only need to have a same static gain. For example, the transistor size of the replica may be smaller than the transistor size of the output stage. In this case, a circuit area can be reduced.

In one embodiment, the feedback circuit may include: a first high-pass filter configured to remove low frequency components of the main output signal; a second high-pass filter configured to remove low frequency components of the dummy output signal; and a differential amplifier configured to receive an output of the first high-pass filter and an output of the second high-pass filter.

### EMBODIMENTS

Embodiments of the present disclosure will be now described with reference to the drawings. Like or equivalent components, members, and processes illustrated in each drawing are given like reference numerals and a repeated description thereof will be appropriately omitted. Further, the embodiments are presented by way of example only and are not intended to limit the present disclosure and invention, and any features or combination thereof described in the embodiments may not necessarily be essential to the present disclosure and invention.

In the present disclosure, “a state where a member A is connected to a member B” includes not only a case where the member A and the member B are physically and directly connected, but also a case where the member A and the member B are indirectly connected via any other member that does not substantially affect an electrical connection state between the members A and B or does not impair functions and effects achieved by combinations of the members A and B.

Similarly, “a state where a member C is installed between a member A and a member B” includes not only a case where the member A and the member C or the member B and the member C are directly connected, but also a case where the member A and the member C or the member B and the member C are indirectly connected via any other member that does not substantially affect an electrical connection state between the members A and C or the members B and C or does not impair functions and effects achieved by combinations of the members A and C or the members B and C.

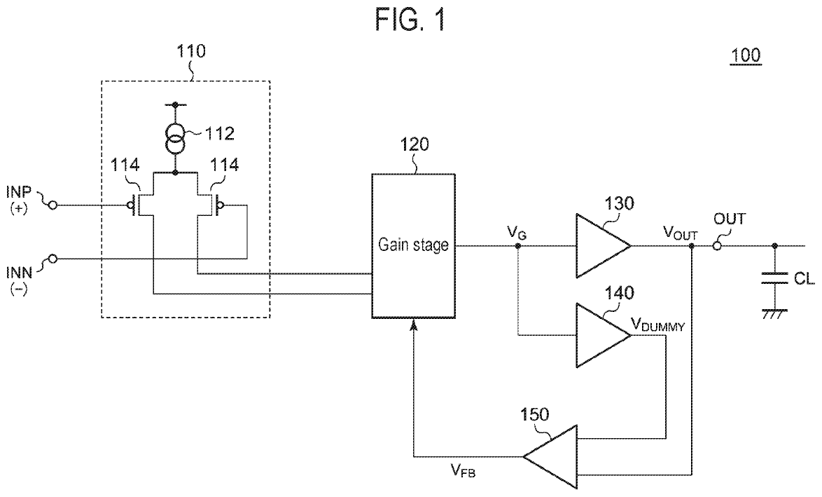

FIG. 1 is a block diagram of an operational amplifier circuit 100 according to an embodiment. The operational amplifier circuit 100 includes a differential input stage 110, a gain stage 120, an output stage 130, a replica 140, and a feedback circuit 150. The operational amplifier circuit 100 includes an inverting input terminal INN (−), a non-inverting input terminal INP (+), and an output terminal OUT. A capacitive load CL may be connected to the output terminal OUT.

The differential input stage 110 includes a tail current source 112 and a differential pair 114. As will be described later, in FIG. 1, the differential pair 114 is PMOS transistors, but the present disclosure is not limited thereto, and the differential pair 114 may be NMOS transistors or a rail-to-rail configuration including a differential pair of an NMOS transistor and a PMOS transistor.

The gain stage 120 amplifies an output signal of the differential input stage 110. The output stage 130 receives an output signal V_{G} of the gain stage 120 and generates a main output signal V_{OUT} at the output terminal OUT.

The replica 140 has the same configuration as the output stage 130 and generates a dummy output signal V_{DUMMY} according to the output signal V_{G} of the gain stage 120. The capacitive load CL may be connected to an output node of the output stage 130, where an output node of the replica 140 is isolated from the capacitive load CL.

The replica 140 and the output stage 130 may be designed so that corresponding transistors have the same size (gate width/gate length: W/L). With this configuration, the replica 140 and the output stage 130 have the same static gain, so that mismatch can be detected with high accuracy.

However, a transistor size of the replica 140 and a transistor size of the output stage 130 may be different from each other. Even when they are different in size, by designing the replica 140 to have substantially the same static gain as the output stage 130, the mismatch can be detected with high accuracy. For example, the transistor size of the replica 140 may be made smaller than the transistor size of the output stage 130, so that an overhead in circuit area due to the addition of the replica 140 can be reduced.

The feedback circuit 150 receives the main output signal V_{OUT} and the dummy output signal V_{DUMMY}. The feedback circuit 150 supplies a feedback signal S_{FB} according to an error (mismatch) between the main output signal V_{OUT} and the dummy output signal V_{DUMMY} to the gain stage 120. As the feedback signal S_{FB} acts on the gain stage 120, the output signal V_{G} of the gain stage 120 changes such that the mismatch approaches zero.

The above is a configuration of the operational amplifier circuit 100. Next, an operation of the operational amplifier circuit 100 will be described.

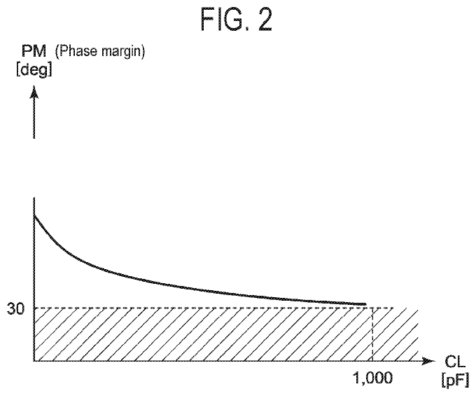

FIG. 2 is a view showing a phase margin of the operational amplifier circuit 100. The horizontal axis represents the load capacitance CL, and the vertical axis represents the phase margin. According to the operational amplifier circuit 100 of FIG. 1, even when the load capacitance CL becomes 1,000 pF or larger, the phase margin can be maintained to be larger than 30 degrees, so that stability can be improved.

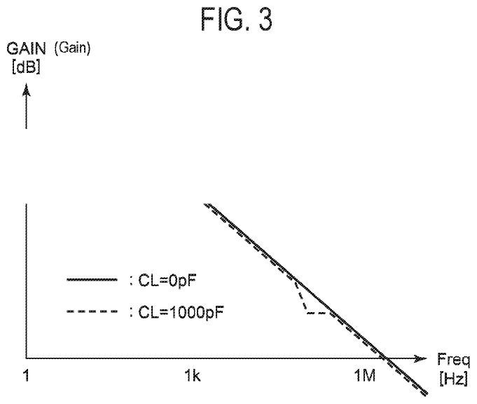

FIG. 3 is a view showing gain characteristics of the operational amplifier circuit 100. The horizontal axis represents a frequency, and the vertical axis represents a gain. FIG. 3 shows gain characteristics when the load capacitance CL is small (for example, 0 pF) and when the load capacitance CL is large (for example, 1,000 pF).

When the load capacitance CL is small, the error (mismatch) between the main output signal V_{OUT} and the dummy output signal V_{DUMMY} is zero, and thus the feedback circuit 150 does not affect an operation of the gain stage 120. That is, when the load capacitance CL is small, unstable feedback that increases GBW (gain-bandwidth product) does not occur.

In contrast, when the load capacitance CL increases, the feedback circuit 150 applies feedback to the gain stage 120 so that the mismatch between the main output signal V_{OUT} and the dummy output signal V_{DUMMY} becomes smaller. As a result, a new zero point is added, and a phase delay of a pole can be canceled.

The present disclosure covers various devices and methods that can be understood as the block diagram or circuit diagram of FIG. 1 or derived from the above description, and is not limited to a specific configuration. More specific configuration examples and modifications will be described below, not to narrow the scope of the present disclosure, but to help understand and clarify the essence and operation of the present disclosure and the present invention.

### EMBODIMENTS

### Example 1

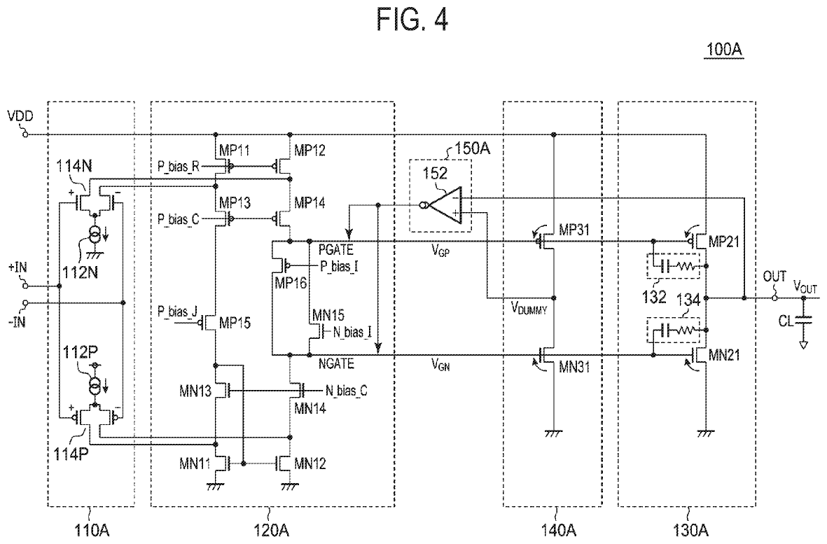

FIG. 4 is a circuit diagram of an operational amplifier circuit 100A according to an embodiment. The operational amplifier circuit 100A is of a rail-to-rail folded cascode type.

A differential input stage 110A includes an N-channel differential pair 114N and a tail current source 112N, and a P-channel differential pair 114P and a tail current source 112P.

A gain stage 120A is a folded cascode circuit and includes PMOS transistors MP11 to MP16 and NMOS transistors MN11 to MN15. A bias voltage P_bias_R is supplied to gates of the transistors MP11 and MP12. A bias voltage P_bias_C is supplied to gates of the transistors MP13 and MP14. A bias voltage P_bias_J is supplied to a gate of the transistor MP15. A bias voltage N_bias_C is supplied to gates of the transistors MN13 and MN14. Gates of the transistors MN11 and MN12 are connected to a drain of the transistor MN13.

An output stage 130A includes a P-channel high-side transistor MP21, an N-channel low-side transistor MN21, and phase compensation circuits 132 and 134.

A replica 140A includes a P-channel high-side transistor MP31 and an N-channel low-side transistor MN31. A gate of the high-side transistor MP31 is connected to a gate of the high-side transistor MP21 of the output stage 130A and receives a common gate signal V_{GP}.

A feedback circuit 150A may include a differential amplifier 152. The differential amplifier 152 amplifies an error between the main output signal V_{OUT} and the dummy output signal V_{DUMMY}. An output of the differential amplifier 152 is supplied to the gain stage 120A and changes gate signals V_{GP} and V_{GN}, which are outputs of the gain stage 120. In addition, the circuit diagram of FIG. 4 does not show that the output of the feedback circuit 150A is directly connected to output nodes of the gain stage 120, but that the output of the feedback circuit 150A changes to the output signals of the gain stage 120. Specifically, the feedback circuit 150A may change at least one of bias voltages of the gain stage 120A according to a feedback signal.

### Example 2

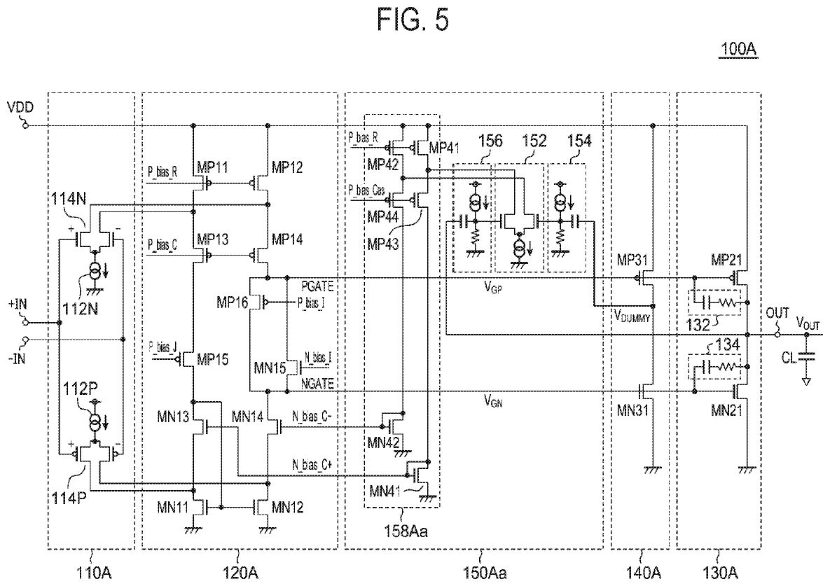

FIG. 5 is a circuit diagram showing an example (100Aa) of the operational amplifier circuit 100A of FIG. 4. In this example, a feedback circuit 150Aa changes the bias voltage N_bias_C supplied to the gates of the transistors MN13 and MN14 of the gain stage 120A.

The feedback circuit 150Aa includes a differential amplifier 152, a first high-pass filter 154, a second high-pass filter 156, and a bias circuit 158Aa.

The bias circuit 158Aa includes P-channel transistors MP41 to MP44 and N-channel transistors MN41 and MN42. The bias voltage P_bias_R is applied to gates of the transistors MP41 and MP42, and the bias voltage P_bias_Cas is applied to gates of the transistors MP43 and MP44.

A voltage N_bias_C+ generated at the gate of the transistor MN41 is supplied to the gate of the transistor MN13, as a feedback signal. Further, a voltage N_bias_C-generated at the gate of the transistor MN42 is supplied to the gate of the transistor MN14, as a feedback signal.

### Example 3

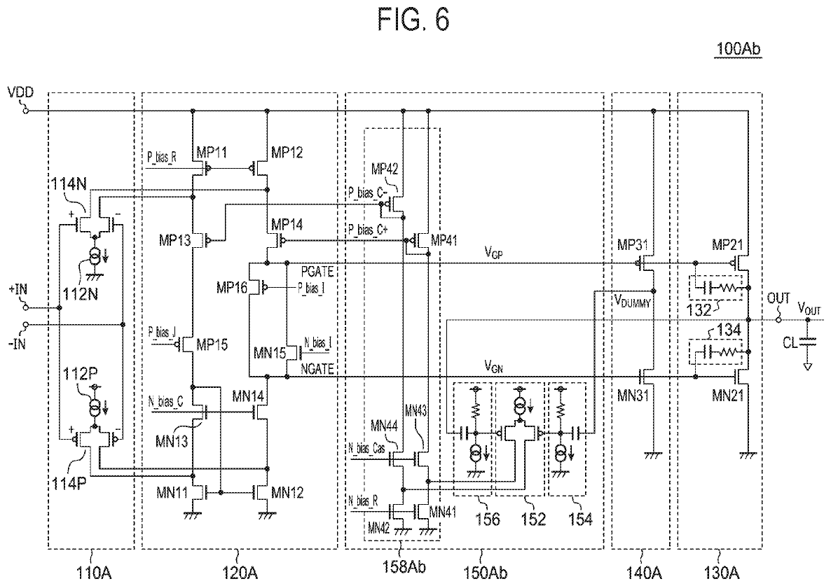

FIG. 6 is a circuit diagram showing an example (100Ab) of the operational amplifier circuit 100A of FIG. 4. In this example, a feedback circuit 150Ab changes the bias voltage P_bias_C supplied to the gates of the transistors MP13 and MP14 of the gain stage 120A.

A configuration of a bias circuit 158Ab is such that the P channel and N channel of the feedback circuit 150Aa in FIG. 5 are substituted with each other and the top and bottom are reversed.

### Example 4

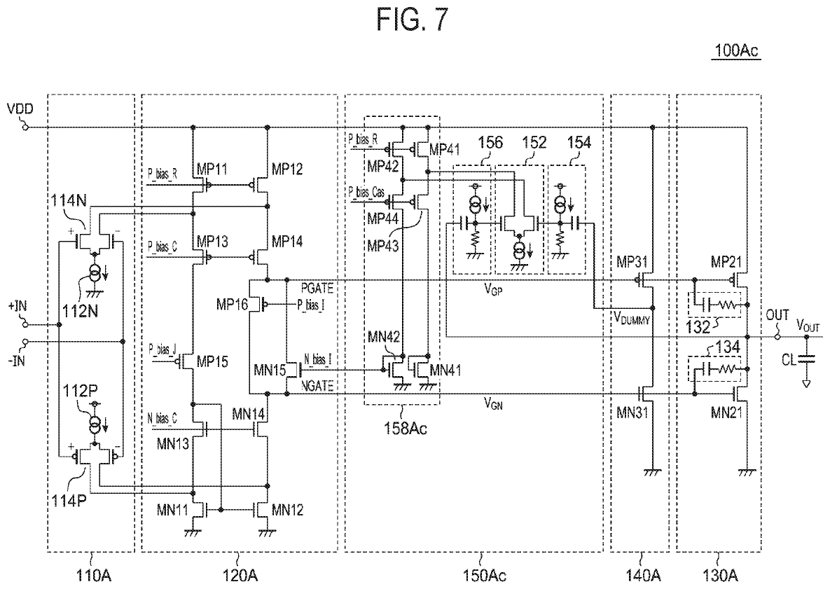

FIG. 7 is a circuit diagram showing an example (100Ac) of the operational amplifier circuit 100A of FIG. 4. In this example, a feedback circuit 150Ac changes a bias voltage N_bias_I supplied to a gate of the transistor MN15 of the gain stage 120A.

A configuration of a bias circuit 158Ac is basically the same as the bias circuit 158Aa in FIG. 5 except that the gate and drain of the transistor MN41 are connected.

### Example 5

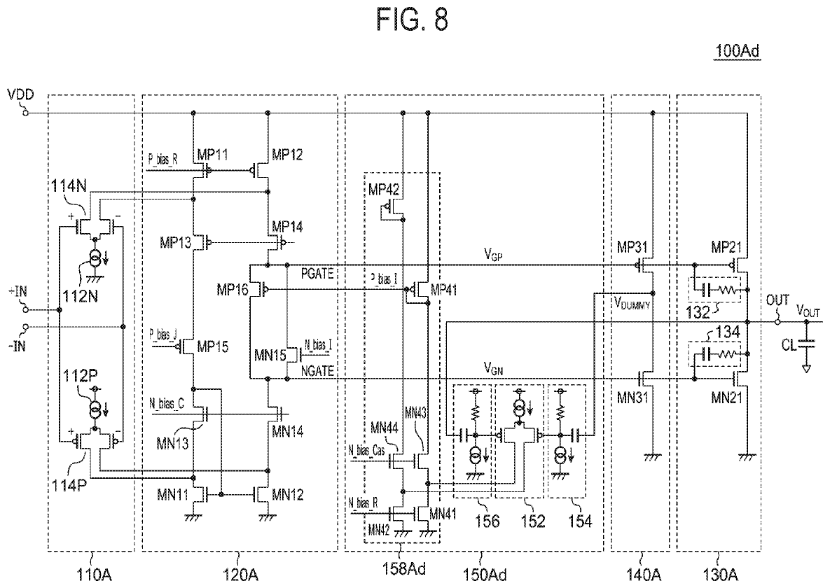

FIG. 8 is a circuit diagram showing an example (100Ad) of the operational amplifier circuit 100A of FIG. 4. In this example, a feedback circuit 150Ad changes the bias voltage P_bias_I supplied to a gate of the transistor MP16 of the gain stage 120A.

A configuration of a bias circuit 158Ad is such that the P channel and the N channel of the bias circuit 158Ac in FIG. 7 are swapped and the top and bottom are reversed, and a gate voltage of the transistor MP41 is fed back to the gate of the transistor MP16.

The configuration of the operational amplifier circuit 100 is not limited to those described above, and various modifications exist. Modifications of the operational amplifier circuit 100 will be described below.

In the embodiments, a rail-to-rail type operational amplifier has been described, but the present disclosure is not limited thereto.

### Modifications of Differential Input Stage 110

### (Modification 1)

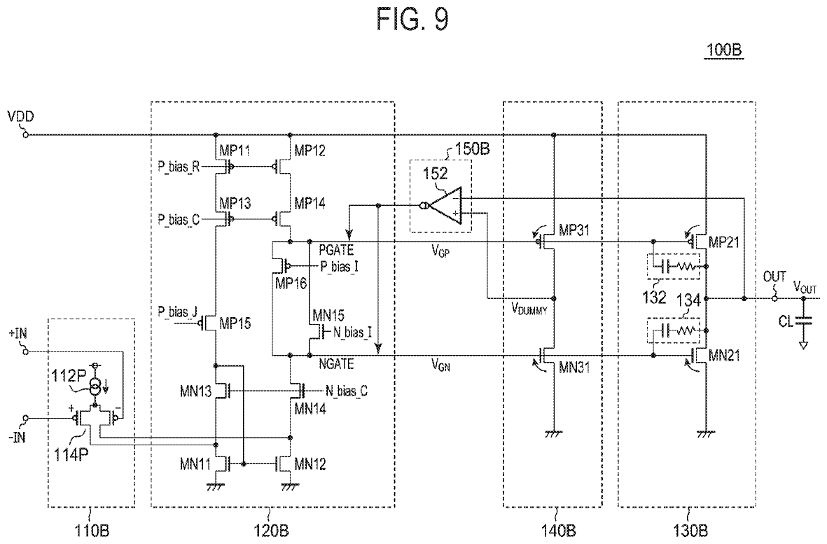

FIG. 9 is a circuit diagram of an operational amplifier circuit 100B according to Modification 1. A differential input stage 110B of the operational amplifier circuit 100B has a P-channel differential input.

A gain stage 120B, an output stage 130B, a replica 140B, and a feedback circuit 150B are the same as the gain stage 120A, the output stage 130A, the replica 140A, and the feedback circuit 150A in FIG. 4.

### (Modification 2)

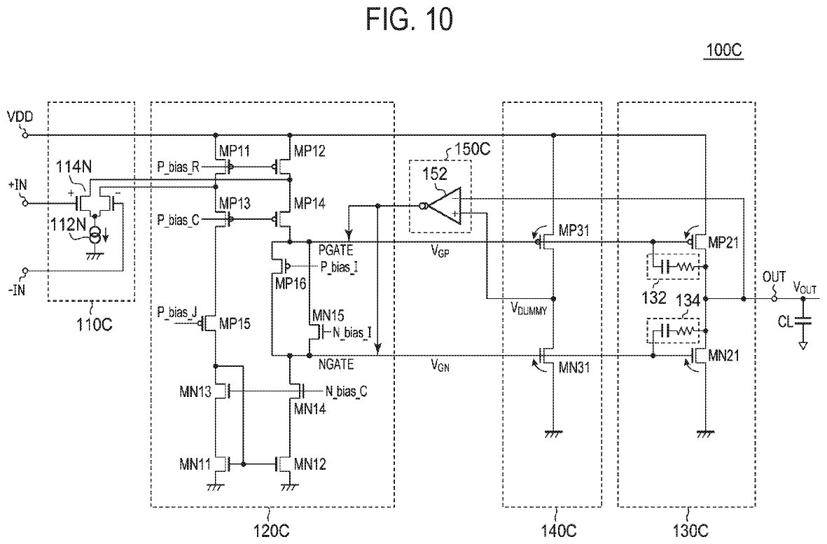

FIG. 10 is a circuit diagram of an operational amplifier circuit 100C according to Modification 2. A differential input stage 110C of the operational amplifier circuit 100C has an N-channel differential input.

A gain stage 120C, an output stage 130C, a replica 140C, and a feedback circuit 150C are the same as the gain stage 120A, the output stage 130A, the replica 140A, and the feedback circuit 150A in FIG. 4.

### Modifications of Gain Stage 120

Modifications of the gain stage 120 are as follows.

### (Modification 3)

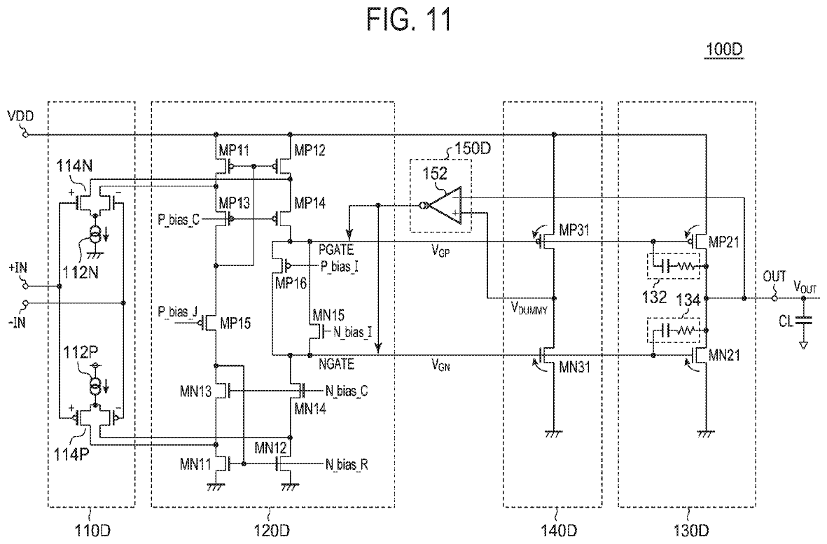

FIG. 11 is a circuit diagram of an operational amplifier circuit 100D according to Modification 3. In a gain stage 120D, the gates of the transistors MP11 and MP12 are connected to the drain of the transistor MP13, and a bias voltage N_bias_R is supplied to the gates of the transistors MN11 and MN12.

A differential input stage 110D, an output stage 130D, a replica 140D, and a feedback circuit 150D are the same as the differential input stage 110D, the output stage 130A, the replica 140A, and the feedback circuit 150A in FIG. 4

### (Modification 4)

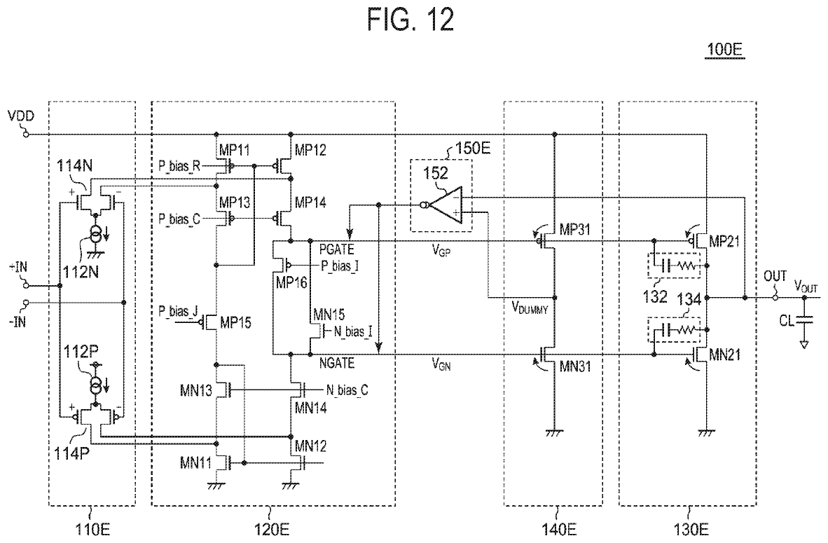

FIG. 12 is a circuit diagram of an operational amplifier circuit 100E according to Modification 4. Modification 4 is different from Modification 3 in terms of a configuration of a gain stage 120E. Specifically, in the gain stage 120E, the bias voltage P_bias_R is supplied to the gates of the transistors MP11 and MP12.

A differential input stage 110E, an output stage 130E, a replica 140E, and a feedback circuit 150E are the same as the differential input stage 110A, the output stage 130A, the replica 140A, and the feedback circuit 150A in FIG. 4.

More specifically, a configuration of the gain stage 120 is not limited to a folded cascode circuit, and the present disclosure is applicable to other types of gain stages.

### Modifications of Output Stage 130

### (Modification 5)

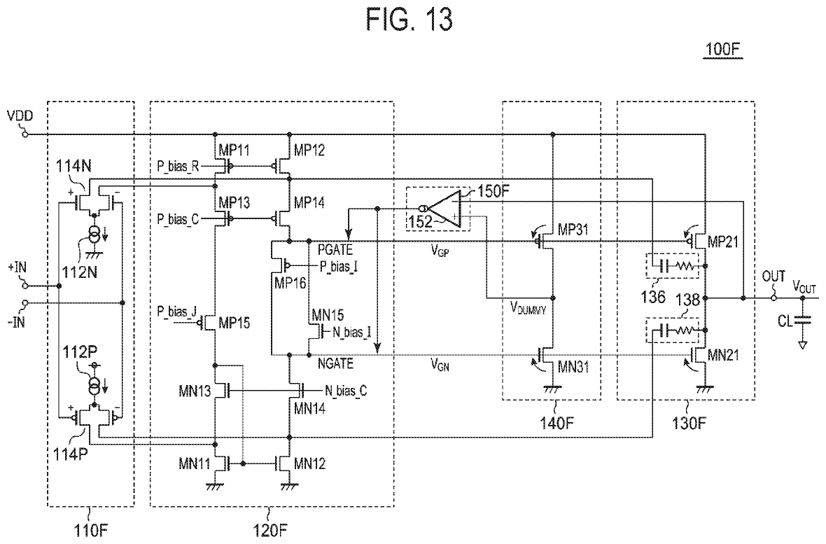

FIG. 13 is a circuit diagram of an operational amplifier circuit 100F according to Modification 5. Modification 5 is different from Examples 1 to 5 in terms of a connection manner of phase compensation circuits of an output stage 130F. Specifically, phase compensation circuits 136 and 138 of the output stage 130F are connected to outputs of a differential input stage 110F.

### (Modification 6)

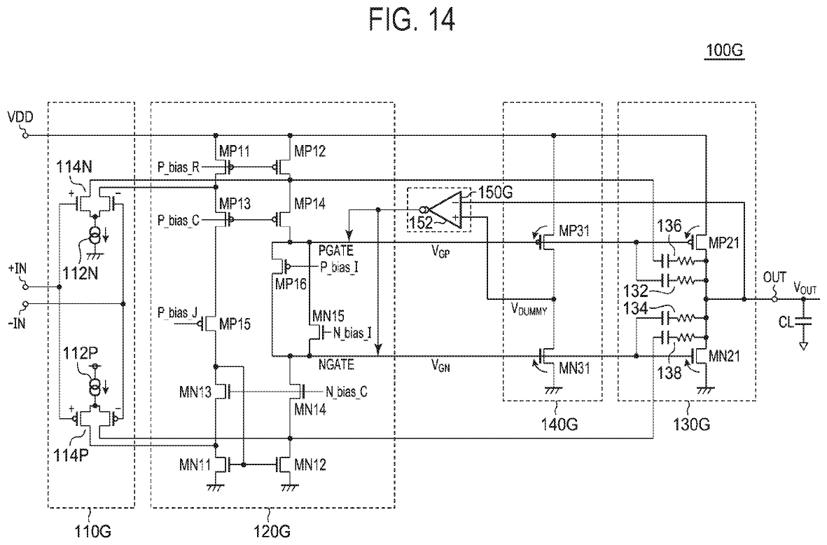

FIG. 14 is a circuit diagram of an operational amplifier circuit 100G according to Modification 6. In Modification 6, an output stage 130G includes both the phase compensation circuits 132 and 134 of Examples 1 to 5 and the phase compensation circuits 136 and 138 of Modification 5.

As the output stage 130, class AB including a PMOS transistor on the high side and an NMOS transistor on the low side has been described, but the present disclosure is not limited thereto. For example, the high side may be an NMOS transistor and the low side may be a PMOS transistor. Alternatively, both the high side and the low side may be NMOS transistors.

Further, the output stage 130 is not limited to class AB, but the present disclosure is also applicable to class A output stages.

The configurations described in the embodiments and modifications can be combined arbitrarily.

The embodiments are illustrative, and it will be understood by those skilled in the art that there are various modifications to the combinations of the constituent elements and processing processes and that such modifications are also included in the present disclosure and may constitute the scope of the present disclosure.

### (Supplementary Notes)

The following techniques are disclosed in the present disclosure.

### (Supplementary Note 1)

An operational amplifier circuit including:
a differential input stage;
a gain stage;
an output stage configured to be connected to a load;
a replica of the output stage without being connected to the load; and
a feedback circuit that receives a main output signal output from the output stage and a dummy output signal output from the replica and supplies a feedback signal according to an error between the main output signal and the dummy output signal to the gain stage.

### (Supplementary Note 2)

The operational amplifier circuit of Supplementary Note 1, wherein the gain stage is a folded cascode circuit, and the feedback signal is supplied as a bias voltage of the gain stage.

### (Supplementary Note 3)

The operational amplifier circuit of Supplementary Note 1 or 2, wherein the output stage is class AB including a first high-side transistor and a first low-side transistor, and wherein the replica includes a second high-side transistor having a gate connected to the gate of the first high-side transistor, and a second low-side transistor having a gate connected to a gate of the first low-side transistor.

### (Supplementary Note 4)

The operational amplifier circuit of any one of Supplementary Notes 1 to 3, wherein the output stage and the replica have a same static gain.

### (Supplementary Note 5)

The operational amplifier circuit of any one of Supplementary Notes 1 to 3, wherein the output stage and the replica have corresponding transistors of a same size.

### (Supplementary Note 6)

The operational amplifier circuit of any one of Supplementary Notes 1 to 5, wherein the feedback circuit includes:
a first high-pass filter configured to remove low frequency components of the main output signal;
a second high-pass filter configured to remove low frequency components of the dummy output signal; and
a differential amplifier configured to receive an output of the first high-pass filter and an output of the second high-pass filter.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An operational amplifier circuit comprising:
a differential input stage;
a gain stage;
an output stage configured to be connected to a load;
a replica of the output stage without being connected to the load; and
a feedback circuit that receives a main output signal output from the output stage and a dummy output signal output from the replica, and supplies a feedback signal according to an error between the main output signal and the dummy output signal to the gain stage.

2. The operational amplifier circuit of claim 1, wherein the gain stage is a folded cascode circuit, and the feedback signal is supplied as a bias voltage of the gain stage.

3. The operational amplifier circuit of claim 1, wherein the output stage is class AB including a first high-side transistor and a first low-side transistor, and
wherein the replica includes a second high-side transistor having a gate connected to a gate of the first high-side transistor, and a second low-side transistor having a gate connected to a gate of the first low-side transistor.

4. The operational amplifier circuit of claim 1, wherein the output stage and the replica have a same static gain.

5. The operational amplifier circuit of claim 1, wherein the output stage and the replica have corresponding transistors of a same size.

6. The operational amplifier circuit of claim 1, wherein the feedback circuit includes:
a first high-pass filter configured to remove low frequency components of the main output signal;
a second high-pass filter configured to remove low frequency components of the dummy output signal; and
a differential amplifier configured to receive an output of the first high-pass filter and an output of the second high-pass filter.
